(19) United States
(12) Patent Application Publication
(10) Pub. No.: US 2009/0008750 A1
(43) Pub. Date: Jan. 8, 2009

(54) SEAL RING FOR SEMICONDUCTOR DEVICE

(76) Inventor: Shunichi Tokitoh, Tokyo (JP)

Correspondence Address: TAFT, STETTINIUS & HOLLISTER LLP, SUITE 1800, 425 WALNUT STREET, CINCINNATI, OH, 45202-3957, US

(21) Appl. No.: 12/142,875

(22) Filed: Jun. 20, 2008

(30) Foreign Application Priority Data
Jul. 4, 2007 (JP) 2007176204

(51) Int. Cl. H01L 21/71; H01L 23/00

(52) U.S. Cl. 257/629; 438/618; 257/E23.194; 257/E21.536

(57) ABSTRACT

A semiconductor device having a seal ring structure with high stress resistance is provided. The semiconductor device is provided with a semiconductor layer including a plurality of semiconductor elements, an insulating film formed on the semiconductor layer, and a body that passes through the insulating film and surrounds the semiconductor elements as a whole. The body includes a plurality of walls that are spaced apart from each other in a circumferential direction and are arranged in parallel with one another, and a plurality of bridges, each of which intersects at least one of the plurality of walls.

### CROSS-REFERENCE TO RELATED APPLICATIONS

This application claims priority under 35. U.S.C. §119 to Japanese Patent Application Serial No. JP2007-176204 filed on Jul. 4, 2007, entitled “SEMICONDUCTOR DEVICE,” the disclosure of which is hereby incorporated by reference.

### FIELD OF THE INVENTION

The present invention relates to a semiconductor device and, more particularly, to a seal ring structure surrounding a semiconductor element for preventing stresses from propagating into the semiconductor element.

Integration at an element level, such as a transistor or the like, has been rapidly enhanced with advances in miniaturization. Accordingly, multi-wiring is required for realizing high integration of a wiring system with an underlying level. However, with the high integration of wiring system, the resulting wiring layer has a signal delay that may interfere with high speed operation. As a result, it is preferable to reduce wiring resistance “R” and inter-wiring capacitance “C” to further high speed operation of a microprocessor or the like.

The wiring resistance R can be significantly reduced by changing a wiring material from aluminum (Al), which has been conventionally used, to copper (Cu). Although Cu is more difficult etch than Al, Cu may form thick films using conventional chemical vapor deposition (CVD) methods providing excellent step coverage or a plating method for filling. Cu may also be used with a damascene method, which refers to a technique in which a groove for wiring is previously formed on an interlayer insulating film. Then, a Cu film is deposited on the entire surface of an insulating film so that the groove is filled with Cu. Thereafter, the remaining Cu, except for the Cu in the groove, is removed using a chemical mechanical polishing (CMP) method to form a Cu wiring in the interlayer insulating film.

Regarding reduction of the inter-wiring capacitance C, one may use a so-called low-k material having a relative dielectric constant lower than that of a conventional dielectric material, such as silicon dioxide (SiO₂), for an interlayer insulating film. Methyl silsesquioxane (MSQ), which is an exemplary low-k material, makes a resulting dielectric film porous as a result of a gap in a molecular structure due to the presence of a methyl group. Such a low-k film having a low film density is highly hygroscopic and shows an increase in dielectric constant due to inclusion of impurities. However, the low-k film may suffer from stress generated in dicing or CMP and, consequently, be apt to break due to its low mechanical strength and/or delaminate between adjacent layers due to lower interfacial adhesion. To overcome these weaknesses of conventional low-k films, the instant invention provides for a seal ring to surround an active region having circuit elements formed therein. By surrounding the active region with a seal ring, it is possible to prevent unintended stresses from propagating into the semiconductor element during CMP or dicing and thus prevent breakage of the low-k film and/or delamination between adjacent layers.

The present invention provides a semiconductor device having a seal ring structure with high stress resistance. According to an aspect of the invention, there is provided a semiconductor device including: a semiconductor layer including a plurality of semiconductor elements; an insulating film formed on the semiconductor layer; and a tubular body that passes through the insulating film and surrounds the semiconductor elements as a whole, in which the tubular body includes a plurality of tubular plugs which are spaced apart from each other in a circumferential direction and are arranged in parallel, and a plurality of wall portions, each of which intersects each of the tubular plugs.

According to the semiconductor device of the present invention, it is possible to enhance stress resistance of a seal ring and, accordingly, enhance stress resistance to the seal ring when using interlayer insulating films with lower dielectric constants.

It is a first aspect of the present invention to provide a semiconductor device comprising: (a) a semiconductor layer including semiconductor elements; (b) an insulating film formed over the semiconductor layer; and (c) a circumscribing body that extends into the insulating film and outlines an area overshadowing at lease a portion of the semiconductor elements, where the circumscribing body includes walls which are spaced apart from each other in a circumferential direction and are arranged substantially in parallel, and bridges interconnecting at least two of the plurality of walls.

In a more detailed embodiment of the first aspect, at least two of the bridges are arranged to be substantially perpendicular to the at least two of the walls. In yet another more detailed embodiment, the walls are arranged at equal circumferential intervals. In a further detailed embodiment, the bridges interconnect the walls in an alternating manner between a right inclination direction and a left inclination direction. In still a further detailed embodiment, the invention further comprises a wiring layer in electrical communication with at least one of the semiconductor elements, where the walls and the at least one wiring layer comprise the same material. In a more detailed embodiment, the walls and the wiring layer comprise copper. In a more detailed embodiment, the wiring layer includes a via plug that is formed through the insulating film that interconnects an upper wiring level and a lower wiring level which are spaced apart from each other, and the walls and bridges are arranged at substantially the same depth as the via plug. In another more detailed embodiment, the insulating film includes a low dielectric constant film whose relative dielectric constant is 3 or less.

It is a second aspect of the present invention to provide a semiconductor device comprising: (a) an active region formed over a semiconductor substrate; (b) a wiring formed over the semiconductor substrate and in electrical communication with the active region; and (c) an insulating barrier separating the active region from a seal ring at least partially circumscribing the active region, the seal ring comprising a first wall spaced apart from a second wall, where a first interconnection spans between the first wall and the second wall.

In a more detailed embodiment of the second aspect the wiring comprises a first wiring plug, and the first wall, the second wall, the first interconnection, and the first wiring plug lie generally along a first level of the semiconductor device. In yet another more detailed embodiment, the wiring comprises a first wiring layer positioned over the first wiring plug and in electrical communication with the first wiring plug, the seal ring includes a first seal wiring layer positioned over the first wall, the second wall, and the first interconnection, the first seal wiring layer in electrical communication with at least one of the first wall, the second wall, and the first interconnection, the first wiring layer lies generally along a second level of the semiconductor device as the first seal wiring layer, and the second level of the semiconductor device is over the first level of the semiconductor device. In a further detailed embodiment, the wiring comprises a second wiring plug, the seal ring includes a third wall, a fourth wall, and a second interconnection, the second interconnection spans between the third wall and the fourth wall, the third wall, the fourth wall, the second interconnection, and the second wiring plug lie generally along a third level of the semiconductor device, and the third level of the semiconductor device is over the second level of the semiconductor device. In still a further detailed embodiment, the wiring comprises a second wiring layer positioned over the second wiring plug and in electrical communication with the second wiring plug, the seal ring includes a second seal wiring layer positioned over the third wall, the fourth wall, and the second interconnection, the second seal wiring layer in electrical communication with at least one of the third wall, the fourth wall, and the second interconnection, the second wiring layer lies generally along a fourth level of the semiconductor device as the second seal wiring layer, and the fourth level of the semiconductor device is over the third level of the semiconductor device.

It is a third aspect of the present invention to provide a method of fabricating a semiconductor device, comprising: (a) forming a first conductive plug within an insulating layer, the first conductive plug in electrical communication with the first wiring layer and within the active region of the semiconductor device; (b) forming a seal ring comprising a first wall, a second wall, and a bridge within an insulating layer outside of the active region of the semiconductor device, where the first wall is spaced apart from the second wall, but connected to the second wall by way of the bridge, where formation of the first conductive plug occurs substantially contemporaneously with the formation of at least one of the first wall, the second wall, and the bridge.

In a more detailed embodiment of the third aspect, the invention further comprises forming a first wiring layer within an insulating layer and within an active region of a semiconductor device, forming a first seal wiring layer within an insulating layer outside of the active region of the semiconductor device, where formation of the first wiring layer and the first seal wiring layer occur substantially contemporaneously.

### BRIEF DESCRIPTION OF THE DRAWINGS

FIG. 1 is a plan view showing a portion of a wafer on which a semiconductor device of the present invention is formed.

FIG. 1B is a plan view showing an enlarged region surrounded by a solid line A in FIG. 1A.

FIG. 2 is a sectional view taken along the line 2-2 in FIG. 1B.

FIG. 3 is a perspective view showing a structure of a seal plug according to an embodiment of the present invention.

FIG. 4 is an enlarged schematic view showing an effect of the present invention for stress applied to a seal ring, in comparison to a conventional structure.

FIGS. 5A through 5H are views showing processes of manufacturing a semiconductor device of the present invention.

FIG. 6 is a plan view showing a portion of a semiconductor device according to a second embodiment of the present invention.

FIG. 7 is a sectional view taken along the line 7-7 in FIG. 6.

FIG. 8 is a perspective view showing a structure of a seal plug according to the second embodiment of the present invention.

FIGS. 9A through 9D are top views showing another structure of the seal plug of the present invention.

### DETAILED DESCRIPTION

The exemplary embodiments of the present invention are described and illustrated below to encompass methods of reducing or eliminating the propagation of unintended stressed into a semiconductor element, as well as structural devices for reducing or eliminating the propagation of unintended stressed into a semiconductor element. Of course, it will be apparent to those of ordinary skill in the art that the preferred embodiments discussed below are exemplary in nature and may be reconfigured without departing from the scope and spirit of the present invention. However, for clarity and precision, the exemplary embodiments as discussed below may include optional steps, methods, and features that one of ordinary skill should recognize as not being a requisite to fall within the scope of the present invention.

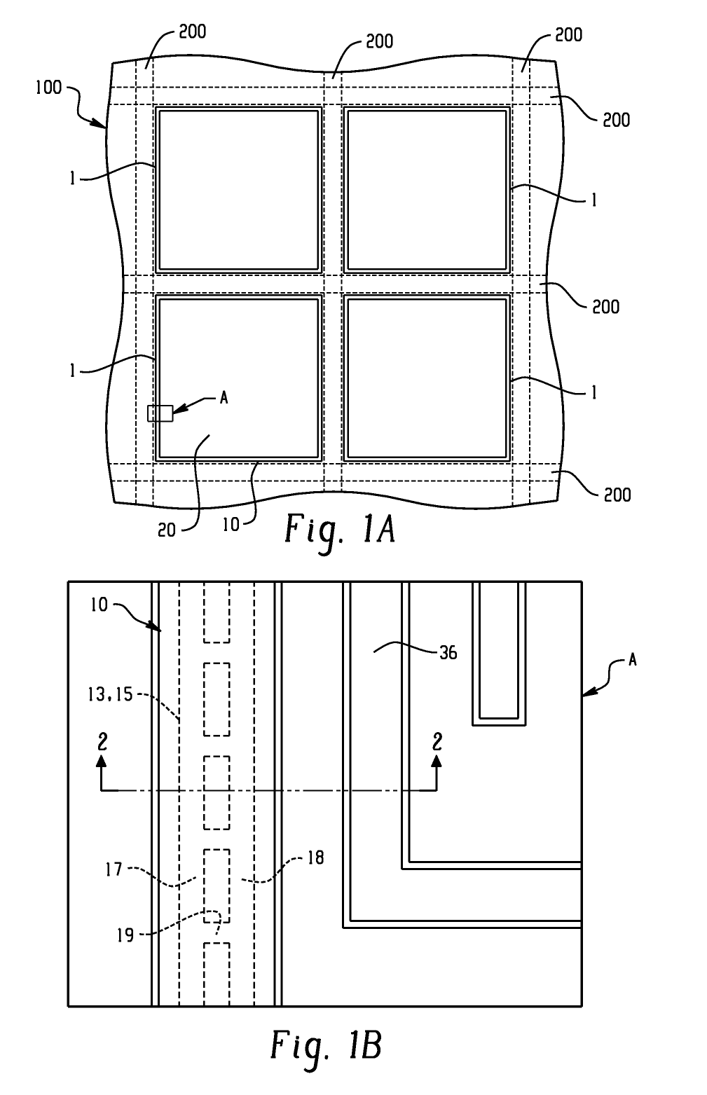

Referencing FIG. 1A, a first exemplary embodiment of the present invention includes a portion of a wafer 100 on which semiconductor devices 1 are formed. The wafer 100 is provided with scribe lines 200 in the form of a lattice, which serve as a cutting margin during a dicing operation. Ultimately, the semiconductor devices 1 are cut into individual segmented chips by dicing the wafer 100 using the scribe lines 200.

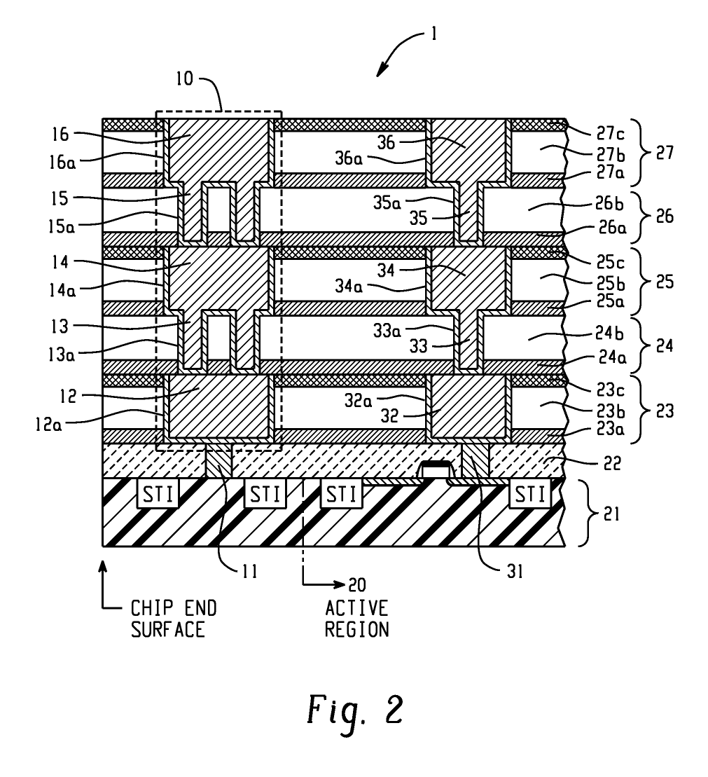

Referring to FIGS. 1A and 1B, each semiconductor device 1 has its own seal ring 10 surrounding the semiconductor device 1 and formed near the scribe lines 200. In exemplary form, the seal rings 10 have a box shape to surround active regions 20 (see e.g., FIG. 2) in which circuit parts are formed near peripheral surfaces of the semiconductor devices 1 that are ultimately cut into chips. Accordingly, the seal rings 10 reduce or prevent local stresses occurring near the chip peripheral surfaces from propagating into the active regions 20.

Referencing FIG. 2, an exemplary semiconductor device 1 includes a semiconductor layer 21 on which circuit elements such as transistors and the like are formed, and a wiring layer in which wirings are formed in three dimensions through a plurality of layers over the semiconductor layer 21. Six interlayer insulating films 22-27, for example, insulate a contact plug 31, via plugs 33, 35, first to third wirings 32, 34, 36, and a seal ring 10. It should be noted that the seal ring 10 is formed through the interlayer insulating films 22-27 proximate an edge of the active region 20.

The first interlayer insulating film 22 is a film formed prior to formation of the metal wiring layers above the semiconductor layer 21. For example, boron-doped phosphosilicate glass (BPSG) or the like is used as the first interlayer insulating film 22. Contact plugs 31, electrically connected to circuit elements, are formed on the semiconductor layer 21 and through the insulating film 22. Likewise, a wall 11 is formed outside of the active region 20, below the seal ring 10, and through the insulating film 22. In exemplary form, the contact plug 31 and the wall 11 are fabricated from, for example, without limitation, tungsten.

The second, fourth and sixth interlayer insulating films 23, 25, 27 have the same laminated structure in which diffusion barrier films 23a, 25a, 27a, low-k films 23b, 25b, 27b, and cap films 23c, 25c, 27c are respectively formed in order. The third and fifth interlayer insulating films 24, 26 have the same laminated structure in which diffusion barrier films 24a, 26a and low-k films 24b, 26b are respectively laminated in order. The diffusion barrier films 23a-27a comprise, for example, without limitation, silicon nitride (SiNₓ) and silicon carbide (SiC), and act as barrier to retard or prevent diffusion of Cu, which comprises the wirings 32, 34, 36 and the seal ring 10. The cap films 23c, 25c, 27c comprise, for example, without limitation, silicon dioxide (SiO₂), silicon carbide (SiC), carbon-doped silicon oxide (SiOC), silicon carbon nitride (SiCN), silicon nitride (SiNₓ), and silicon-oxynitride (SiON), which act as surface protection layer for the low-k films 23b-27b. The low-k films 23b-27b comprise a material having a relatively low dielectric constant in order to suppress an RC delay. Exemplary low-k films include, without limitation, methyl silsesquioxane (MSQ), hydrogen silsesquioxane (HSQ), carbon-doped oxide (CDO), polymers (including polyimides, parylenes, Teflons, copolymers, etc.), and amorphous carbons. In exemplary form, the relative dielectric constant of the low-k film material may be less than 3.0.

The first wiring 32 is formed in the second interlayer insulating film 23, while the second wiring 34 is formed in the fourth interlayer insulating film 25, and further the third wiring 36 is formed in the sixth interlayer insulating film 27. The first wiring 32 is electrically connected to the circuit elements, which are formed on the semiconductor layer 21, by way of the contact plug 31. The via plug 33 is formed in the third interlayer insulating film 24 and electrically interconnects the first wiring 32 and the second wiring 34. The via plug 35 is formed in the fifth interlayer insulating film 26 and electrically interconnects the second wiring 34 and the third wiring 36. These wirings and via plugs use Cu having relatively low electrical resistance in order to suppress signal delay. Since Cu has a large diffusion coefficient and thus is apt to diffuse into adjacent material, barrier metal layers 32a-36a are utilized to inhibit this diffusion and may comprise, for example, without limitation, tantalum (Ta), tantalum nitride (TaN), tungsten (W), tungsten nitride (WN), tungsten silicide (WSi), titanium (Ti), titanium nitride (TiN), and titanium silicon nitride (TiSiN).

The seal ring 10 is fabricated from a combination of components formed through the interlayer insulating films 23-27. In other words, the seal ring 10 includes a first seal wiring 12 formed in the second interlayer insulating film 23 and connected to the wall 11, a second seal wiring 14 formed in the fourth interlayer insulating film 25, and a third seal wiring 16 formed in the sixth interlayer insulating film 27. A frame 13, in exemplary form, is integrally formed with the second seal wiring 14 in the third interlayer insulating film 24 and connected to the first seal wiring 12, while another frame 15, in exemplary form, is integrally formed with the third seal wiring 16 in the fifth interlayer insulating film 26 and connected to the second seal wiring 14. That is, the seal ring 10 is formed to pass through the interlayer insulating films 23-27 by alternately forming the seal wirings 12, 14, 16 and the dual walls 13, 15. These seal wirings 12, 14, 16 and frames 13, 15 comprise the same copper as the wirings formed in the active region 20. Accordingly, barrier metal layers 12a-16a are formed on surfaces of these seal wirings and seal plugs to retard or eliminate diffusion of Cu, where the barrier metal layers 12a-16a in exemplary form may comprise, without limitation, Ta, TaN, W, WN, WSi, Ti, TiN, and TiSiN.

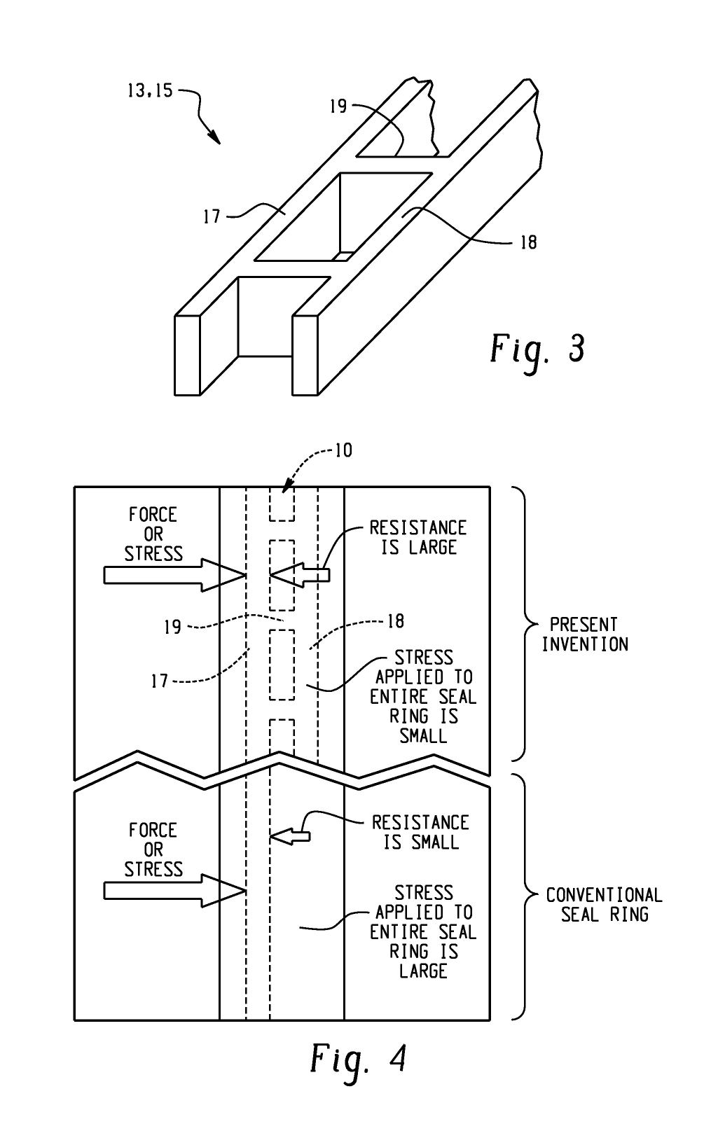

As shown in FIGS. 1B-3, the frames 13, 15 include two rail segments 17, 18 connected to one another by a series of spaced apart transverse portions 19 arranged substantially perpendicular to the two trail segments 17, 18. In other words, as shown in FIGS. 1B-3, the frames 13, 15 have a ladder structure where the rails of the ladder comprise the rail segments 17, 18 and rungs of the ladder comprise the transverse portions 19. This structure promotes enhanced mechanical strength of the seal ring 10. In addition, since the transverse portions 19 intersect the two rail segments 17, 18 at substantially equal intervals, the whole seal ring 10 is reinforced, which further enhances mechanical strength. Accordingly, it is possible to avoid or at least minimize seal ring 10 breakage problems even when using a relatively weak low-k film as a dielectric layer.

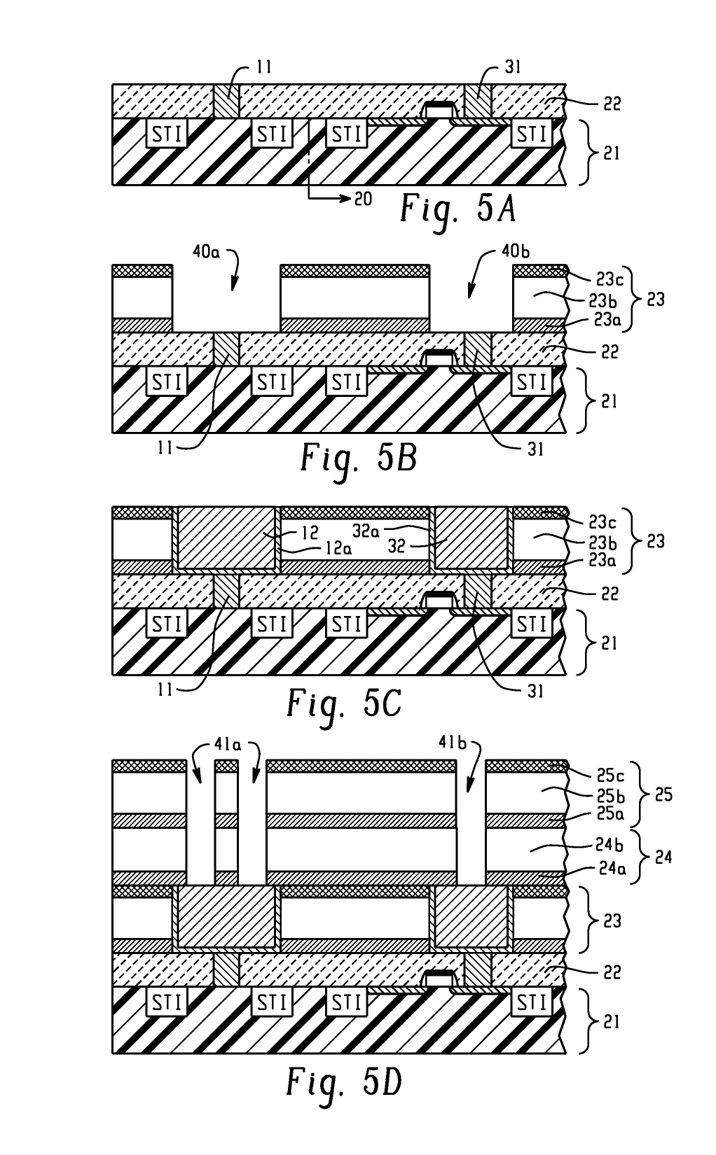

Referencing FIG. 4, the increased strength of the seal ring 10 results from the transverse portions 19 intersecting the rail segments 17, 18 in a substantially perpendicular arrangement. More specifically, since the direction in which the stress acts coincides with a longitudinal direction of the transverse portions 19, stress resistance of the transverse portions 19 can be increased. Since the transverse portions 19 bear the brunt of the external stress and have increased resistance to the external stress, the overall stress applied to the rail segments 17, 18 of the seal ring 10 can be significantly reduced.

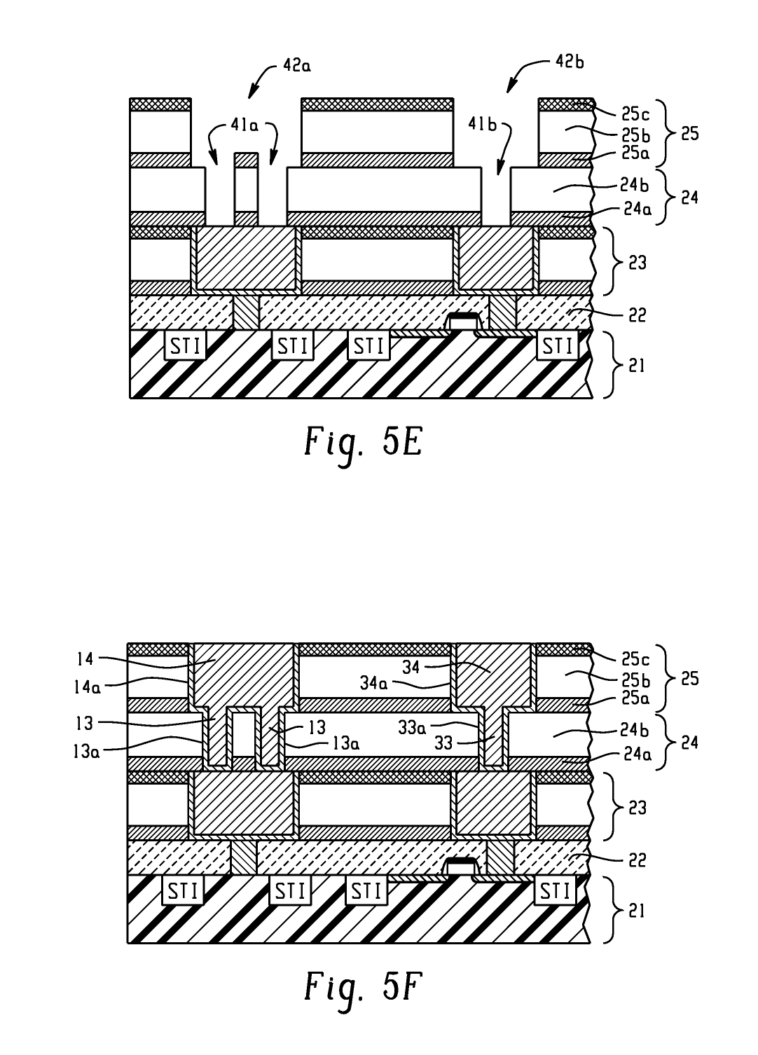

Referencing FIG. 5A, manufacturing the exemplary semiconductor device 1 includes fabricating circuit elements, such as transistors, in the active region 20 of the semiconductor layer 21 (wafer) utilizing known circuit element forming processes. Thereafter, for example, a BPSG film is deposited on the wafer over which the circuit elements are formed, and then the first interlayer insulating film 22 is formed through a reflow flattening process in an nitrogen (N₂) atmosphere at approximately 850° C. Next, openings for formation of the contact plug 31 and the wall 11 are formed in the flattened BPSG film 22. Tungsten then tills the openings by conventional CVD methods using tungsten hexafluoride (WF₆) and hydrogen (H₂) as reaction gases to form the tungsten plug 31 and wall 11. In addition to selectively filling only the openings in the first interlayer insulating film 22, it is also within the scope of the invention to form tungsten on the first interlayer insulating film 22 outside of the openings that is ultimately removed by a CMP process or the like, where the CMP process is also operative to flatten the first interlayer insulating film 22.

Referring to FIG. 5B, the second interlayer insulating film 23 is formed on top of the first interlayer insulating film 22 and over the tungsten plug 31 and wall 11. To accomplish formation of the second interlayer insulating film 23, a SiN diffusion barrier film 23a is deposited at thickness of 5 to 200 nanometers on top of the first interlayer insulating film 22 by a plasma CVD method. The diffusion barrier film 23a prevents Cu of the wirings 32, 34, 36 and seal ring 10 from diffusing into the first interlayer insulating film 22. Next, the low-k film 23b is formed at thickness of 100 to 5000 nanometers on top of the diffusion barrier film 23a. For example, methyl silsesquioxane (MSQ) may be used as the low-k film. The low-k film 23b may be formed using a spin on dielectric (SOD) method, followed by an annealing step. Alternatively, the low-k film 23b may be formed using a CVD method instead of the SOD method. After forming the low-k film 23b, the exposed surface of the low-k film 23b may be irradiated with a helium plasma. This irradiation step improves adhesion to a cap film 23c formed on top of the low-k film 23b, thereby reducing or preventing interfacial delamination. Next, a SiO₂ cap film 23c is deposited at thickness of 5 to 200 nanometers on top of the low-k film 23b by a CVD method using silane (SiH₄) and oxygen (O₂) as reaction gases. The cap film 23c acts as a hard mask when the low-k film is etched, which will be described later, in addition to a surface protection film for the low-k film 23b. In sum, the second interlayer insulating film 23 includes a compilation of films including a diffusion barrier film 23a, a low-k film 23b, and a cap film 23c. After the insulating film 23 has been formed, a photomask (not shown) having openings therethrough is formed on the cap film 23c where the first wiring 32 and the first seal wiring 12 are to be formed. Subsequently, the cap film 23c, the low-k film 23b, and the diffusion barrier film 23a are etched by an anisotropic dry etching process to form wiring grooves 40a and 40b that will ultimately be filled with a conductive material to comprise the first wiring 32 and the first seal wiring 12.

As shown in FIG. 5C, a barrier metal layer 12a, 32a comprising TiN is deposited at thickness of 2 to 50 nanometers on the bottom and lateral sides of the wiring grooves 40a, 40b using a sputtering method. The barrier metal layers prevent Cu, which comprises the wiring material 12, 32, from diffusing into adjacent layers/features. Alternatively, the barrier metal layers 12a, 32a may be formed using a CVD method where titanium tetrachloride (TiCl₄) and ammonia (NH₃) comprise the reaction gases. Next, Cu is deposited to fill the wiring grooves 40a, 40b by an electroplating method to concurrently form the first wiring 32 and the first seal wiring 12. In addition, before the bulk Cu deposition to form the wirings 12, 32, a Cu seed film may be deposited, using a known CVD method. Subsequent to the Cu deposition, for example, an annealing process is performed in an N₂ atmosphere at approximately 250° C. Thereafter, the Cu film deposited on the cap film 23c is removed by a CMP method, which is also operative to flatten the surface of the cap film 23c and wirings 12, 32. In the process of removing the Cu film, an exemplary polishing pressure is set to between 2.5 to 4.5 psi and a relative speed between a polishing pad and the wafer is set to between 60 to 80 meters/min. Accordingly, the first wiring 32 and the first seal wiring 12 are formed in the wiring grooves 40a, 40b by a damascene process.

Referencing FIG. 5D, the third interlayer insulating film 24 and the fourth interlayer insulating film 25 are formed sequentially over the first wiring 32 and the first seal wiring 12. The third interlayer insulating film 24 comprises a diffusion barrier film 24a and a low-k film 24b, while the fourth interlayer insulating film 25 comprises a diffusion barrier film 25a, a low-k film 25b, and a cap film 25c. The diffusion barrier film, the low-k film, and the cap film are formed in the same way as the method of forming the second interlayer insulating film 23. After forming the third and fourth interlayer insulating films 24, 25, a photomask (not shown) having openings formed therethrough is located where the via plug 33 and the frame 13 are to be formed. Thereafter, the third and fourth interlayer insulating films 24, 25 are etched by an anisotropic dry etching process to form wiring grooves 41a, 41b. In exemplary form, the wiring grooves 41a, 41b are formed to have the same widthwise dimension.

Referring to FIG. 5E, a photomask (not shown) is formed on the cap film 25c. Openings are formed through the photomask corresponding to locations where the second wiring 34 and the second seal wiring 14 are to be formed. Thereafter, the fourth interlayer insulating film 25 is etched by an anisotropic dry etching process to form wiring grooves 42a, 42b in which the second wiring 34 and the second seal wiring 14 are formed.

As shown in FIG. 5F, a barrier metal layer 13a, 14a, 33a, 34a of TiN is deposited using conventional sputtering methods on the bottom and lateral sides of the wiring grooves 41a, 41b, 42a, 42b formed in the third and fourth interlayer insulating films 24, 25. Next, Cu is deposited to fill the wiring grooves 41a, 41b, 42a, 42b by an electroplating method to form the via plug 33, the second wiring 34, the frame 13, and the second seal wiring 14 concurrently. That is, the via plug 33, the second wiring 34, the frame 13, and the second seal wiring 14 are formed by a dual damascene process. After depositing the Cu, the Cu may be annealed in, for example, an N₂ atmosphere at approximately 250° C. Thereafter, the Cu remaining on the cap film 25c is removed by a CMP method that flattens the entire surface comprising exposed portions of the cap film 25c, the second wiring 34, and the second seal wiring 14.

Referencing FIG. 5G, the fifth interlayer insulating film 26 and the sixth interlayer insulating film 27 are formed consecutively. The fifth interlayer insulating film 26 includes a diffusion barrier film 26a and a low-k film 26b, similar to the third interlayer insulating film 24, and the sixth interlayer insulating film 27 includes a diffusion barrier film 27a, a low-k film 27b, and a cap film 27c, similar to the second and fourth interlayer insulating films 23, 25. The diffusion barrier film, the low-k film, and the cap film that comprise the fifth and sixth interlayer insulating films 26, 27 are formed in the same way as the method of forming the second and third interlayer insulating films 23, 24. Next, a wiring grooves 43a, 43b, 44a, 44b are formed in the fifth and sixth interlayer insulating films 26, 27. These wiring grooves are formed in the same way as the method of forming the wiring grooves 41a, 41b, 42a, 42b in the third and fourth interlayer insulating films 24, 25.

Referring to FIG. 5H, a barrier metal layer 15a, 16a, 35a and 36a of TiN is sputter deposited on the bottom and lateral sides of the wiring grooves 43a, 43b, 44a, 44b formed in the fifth and sixth interlayer insulating films. Next, Cu is deposited to fill the wiring grooves 43a, 43b, 44a, 44b by an electroplating method to concurrently form the via plug 35, the third wiring 36, the frame 15, and the third seal wiring 16. That is, the via plug 35, the third wiring 36, the frame 15, and the third seal wiring 16 are formed by a dual damascene process. After depositing the Cu, this material is optionally annealed in, for example, an N₂ atmosphere at approximately 250° C. Thereafter, the Cu deposited on the cap film 25c is removed by a CMP method that results in flattening of the polished surface.

Although the foregoing exemplary embodiment has described the formation of the seal plugs, the seal wirings, the via plugs, and the circuit wirings using a dual damascene method, it is also within the scope of the invention to utilize a single damascene method to form these features. In other words, after the seal plugs and the via plugs are formed in the interlayer insulating films, an interlayer insulating film may be formed thereon and only the seal wirings and circuit wirings may be formed on top of the interlayer insulating film by a damascene method.

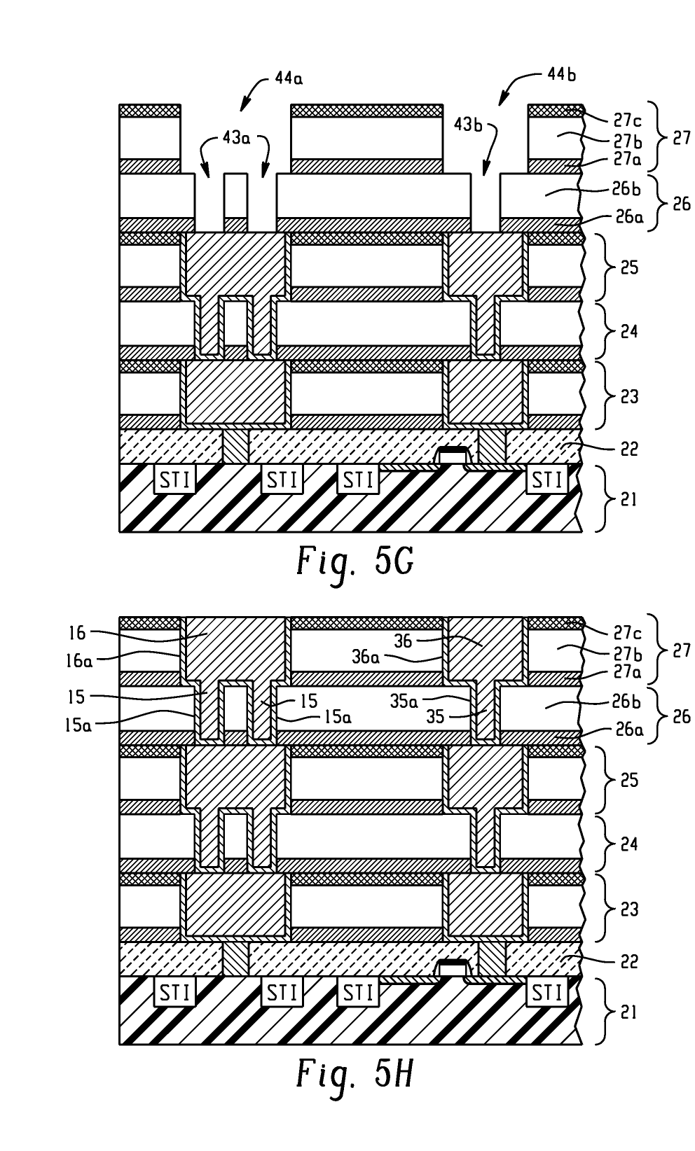

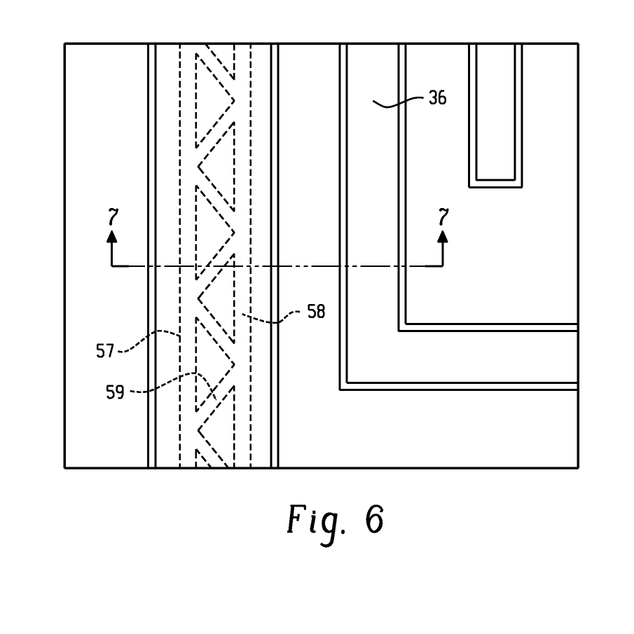

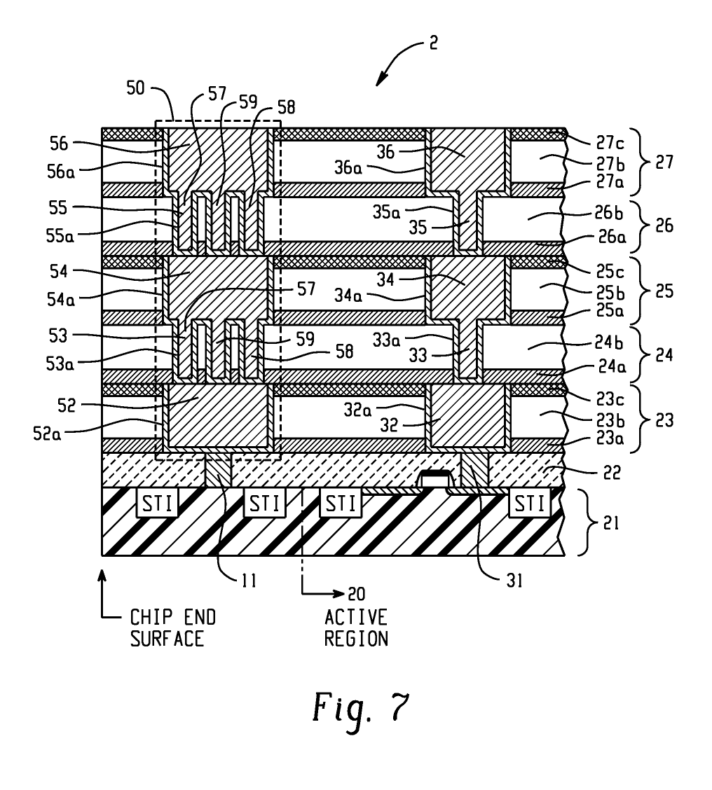

Referring to FIGS. 6 and 7, a second exemplary semiconductor device 2 includes a seal ring 50 having a pair of parallel linear sections 57, 58 held in alignment using a connective structure 59. In this second exemplary embodiment, the connective structure comprises angled connectors 59 spanning between the linear sections 57, 58 an angles other than 90°. The linear sections 57, 58, comprising frames 53, 55, are formed through the third interlayer insulating film 24 and the fifth insulating film 26. The frame 53 is connected to a first seal wiring 52 and a second seal wiring 54. In addition, the second frame 55 is provided in the fifth interlayer insulating film 26 and is connected to the second seal wiring 54 and a third seal wiring 56.

This second exemplary structure 2, like the first exemplary structure 1, allows enhancement to the mechanical strength of the seal ring 50. That is, the seal ring 50 includes a double walled structure 57, 58 with an interconnecting structure 59 therebetween. In this second exemplary embodiment, since the connective structure 59 that intersects the two parallel linear sections 57, 58 in an alternating pattern provides reinforcement in multiple directions against mechanical stresses. Accordingly, like the first embodiment, it is possible to avoid a problem of breakage of the seal ring 50 even when stresses are applied to the seal ring 50 when using a weaker low-k film.

This second exemplary semiconductor device 2 may be manufactured through the same manufacturing process as the semiconductor device 1 of the first embodiment, but using the angled interconnecting structure 59. Obviously, those skilled in the art will understand that certain modifications will need to be made including modifying the shape of the photomask used to etch the wiring grooves of the frames 53 and 55.

Those skilled in the art will recognize from the above description that it is possible to enhance the strength of the seal ring. This results, in exemplary form, from constructing the seal ring so that the wall portions are arranged to intersect the tubular plug in the perpendicular or inclined direction. Accordingly, even when the mechanical strength of the seal ring is weakened by using a low dielectric constant of the interlayer insulating films, it remains possible to prevent breakage of the seal ring. In addition, since the seal ring includes reinforced mechanical strength, applied stresses are prevented from propagating into the active region, which results in less adverse effects on circuit portions.

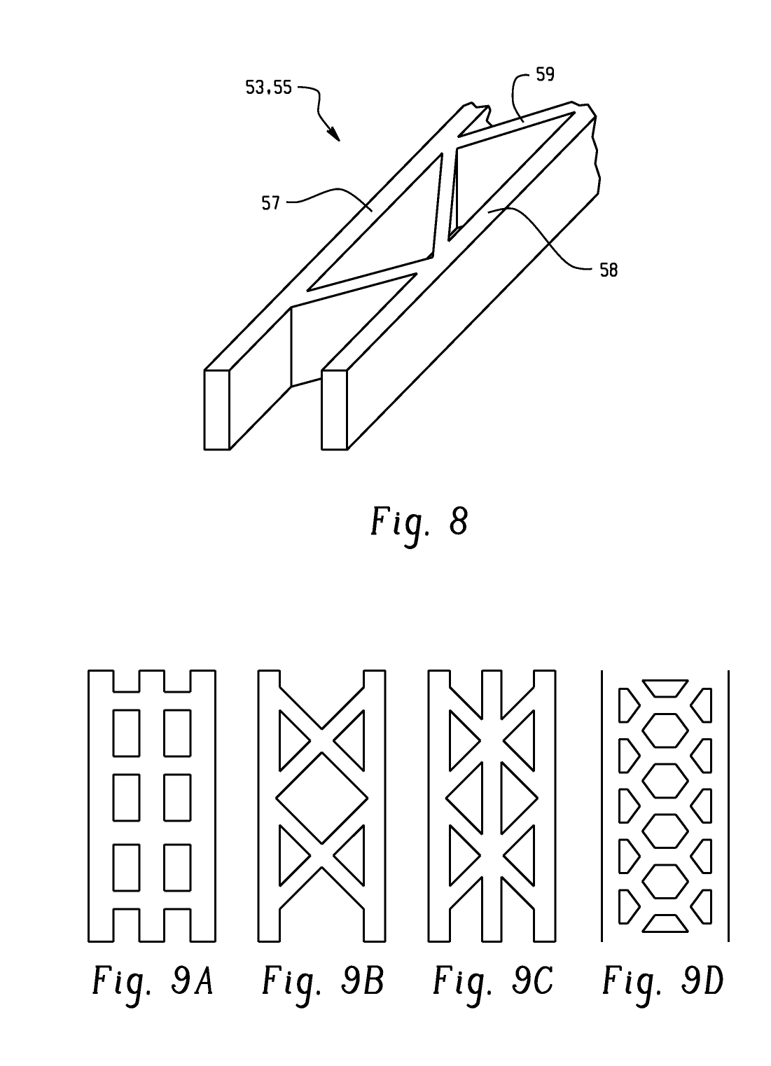

Referencing FIGS. 9A-9D, additional alternate exemplary seal rings include a seal plug structure similar to that of the first embodiment. FIGS. 9A and 9C include exemplary seal rings having three parallel structures spaced from each other. FIG. 9B shows a seal ring structure similar to that of the second embodiment except that components of the wall portions actually intersect the two parallel tubular plugs in the right inclination direction and the left inclination direction between the tubular plugs. In other words, the wall portions have an X shape. Finally, FIG. 9D shows wall portions having a so-called honeycombed structure.

Following from the above description and invention summaries, it should be apparent to those of ordinary skill in the art that, while the methods and apparatuses herein described constitute exemplary embodiments of the present invention, the invention contained herein is not limited to this precise embodiment and that changes may be made to such embodiments without departing from the scope of the invention as defined by the claims. Additionally, it is to be understood that the invention is defined by the claims and it is not intended that any limitations or elements describing the exemplary embodiments set forth herein are to be incorporated into the interpretation of any claim element unless such limitation or element is explicitly stated. Likewise, it is to be understood that it is not necessary to meet any or all of the identified advantages or objects of the invention disclosed herein in order to fall within the scope of any claims, since the invention is defined by the claims and since inherent and/or unforeseen advantages of the present invention may exist even though they may not have been explicitly discussed herein.

What is claimed is:

1. A semiconductor device comprising:
a semiconductor layer including semiconductor elements;
an insulating film formed over the semiconductor layer; and
a circumscribing body that extends into the insulating film and outlines an area overshadowing at lease a portion of the semiconductor elements,
wherein the circumscribing body includes walls which are spaced apart from each other in a circumferential direction and are arranged substantially in parallel, and bridges interconnecting at least two of the plurality of walls.

2. The semiconductor device according to claim 1,
wherein at least two of the bridges are arranged to be substantially perpendicular to the at least two of the walls.

3. The semiconductor device according to claim 2,
wherein the walls are arranged at equal circumferential intervals.

4. The semiconductor device according to claim 1,
wherein the bridges interconnect the walls in an alternating manner between a right inclination direction and a left inclination direction.

5. The semiconductor device according to claim 1, further comprising a wiring layer in electrical communication with at least one of the semiconductor elements, where the walls and the at least one wiring layer comprise the same material.

6. The semiconductor device according to claim 5, where the walls and the Wiring layer comprise copper.

7. The semiconductor device according to claim 5, wherein:
the wiring layer includes a via plug that is formed through the insulating film that interconnects an upper wiring level and a lower wiring level which are spaced apart from each other; and
the walls and bridges are arranged at substantially the same depth as the via plug.

8. The semiconductor device according to claim 1,
wherein the insulating film includes a low dielectric constant film whose relative dielectric constant is 3 or less.

9. A semiconductor device comprising:
an active region formed over a semiconductor substrate;
a wiring formed over the semiconductor substrate and in electrical communication with the active region; and
an insulating barrier separating the active region from a seal ring at least partially circumscribing the active region, the seal ring comprising a first wall spaced apart from a second wall, where a first interconnection spans between the first wall and the second wall.

10. The semiconductor device of claim 9, wherein:
the wiring comprises a first wiring plug; and
the first wall, the second wall, the first interconnection, and the first wiring plug lie generally along a first level of the semiconductor device.

11. The semiconductor device of claim 10, wherein:
the wiring comprises a first wiring layer positioned over the first wiring plug and in electrical communication with the first wiring plug;
the seal ring includes a first seal wiring layer positioned over the first wall, the second wall, and the first interconnection, the first seal wiring layer in electrical communication with at least one of the first wall, the second wall, and the first interconnection; and
the first wiring layer lies generally along a second level of the semiconductor device as the first seal wiring layer;
the second level of the semiconductor device is over the first level of the semiconductor device.

12. The semiconductor device of claim 11, wherein:
the wiring comprises a second wiring plug; and
the seal ring includes a third wall, a fourth wall, and a second interconnection;
the second interconnection spans between the third wall and the fourth wall;
the third wall, the fourth wall, the second interconnection, and the second wiring plug lie generally along a third level of the semiconductor device; and
the third level of the semiconductor device is over the second level of the semiconductor device.

13. The semiconductor device of claim 12, wherein:
the wiring comprises a second wiring layer positioned over the second wiring plug and in electrical communication with the second wiring plug;
the seal ring includes a second seal wiring layer positioned over the third wall, the fourth wall, and the second interconnection, the second seal wiring layer in electrical communication with at least one of the third wall, the fourth wall, and the second interconnection;
the second wiring layer lies generally along a fourth level of the semiconductor device as the second seal wiring layer; and
the fourth level of the semiconductor device is over the third level of the semiconductor device.

14. A method of fabricating a semiconductor device, comprising:
forming a first conductive plug within an insulating layer, the first conductive plug in electrical communication with the first wiring layer and within the active region of the semiconductor device;
forming a seal ring comprising a first wall, a second wall, and a bridge within an insulating layer outside of the active region of the semiconductor device, where the first wall is spaced apart from the second wall, but connected to the second wall by way of the bridge;
wherein formation of the first conductive plug occurs substantially contemporaneously with the formation of at least one of the first wall, the second wall, and the bridge.

15. The method of claim 14, further comprising:
forming a first wiring layer within an insulating layer and within an active region of a semiconductor device;
forming a first seal wiring layer within an insulating layer outside of the active region of the semiconductor device; and
wherein formation of the first wiring layer and the first seal wiring layer occur substantially contemporaneously.
